(19) United States
(12) Patent Application Publication
(10) Pub. No.: US 2026/0206196 A1
(43) Pub. Date: Jul. 16, 2026

(54) SUBSTRATE SUPPORT MEMBER ATTACHMENT AND ASSEMBLY JIG FOR SUBSTRATE SUPPORT MEMBER ATTACHMENT

(71) Applicant: FUJI CORPORATION, Chiryu (JP)

(72) Inventor: Yoshimune YOKOI, Kiyosu-shi (JP)

(73) Assignee: FUJI CORPORATION, Chiryu (JP)

(21) Appl. No.: 19/135,554

(22) PCT Filed: Dec. 27, 2022
(86) PCT No.: PCT/JP2022/048269

§ 371 Date: Jun. 4, 2025

(51) Int. Cl. H05K 13/00; B66F 9/06

(52) U.S. Cl. CPC H05K 13/0069; B66F 9/063

(57) ABSTRACT

A board support member attachment is attached to a board support member configured to support a board when the board support member is held by a conveyance jig and conveyed to a board work machine, the board support member attachment includes: a first support member attached to a first side of the board support member; a second support member attached to a second side of the board support member facing the first side; a coupling section configured to couple the first support member and the second support member such that an interval between the first support member and the second support member is adjustable; and a held section held by the conveyance jig.

### TECHNICAL FIELD

The present description discloses a board support member attachment and an assembly jig for a board support member attachment.

### BACKGROUND ART

Conventionally, disclosed has been a thing for use in a printing device for printing solder on a board, the thing being for moving a board support member that supports a board from below between a printer and a storage shelf in a state of being held by a conveyance jig (for example, Patent Literature 1).

### CITATION LIST

### Patent Literature

Patent Literature 1: WO 2016/199207

### BRIEF SUMMARY

### Technical Problem

The board support member may be held by the conveyance jig via a board support member attachment. A width of the board varies depending on a type of the board. Therefore, when the board support member is attached to the conveyance jig via the board support member attachment, it is necessary to prepare the board support member attachment corresponding to the width of the board.

A main object of the present disclosure is to attach a board support member to a conveyance member via a board support member attachment regardless of a width of a board.

The present disclosure employs the following means in order to achieve the main object described above.

### Solution to Problem

A first board support member attachment according to the present disclosure is a board support member attachment attached to a board support member configured to support a board when the board support member is held by a conveyance jig and conveyed to a board work machine, the board support member attachment includes:
a first support member attached to a first side of the board support member;
a second support member attached to a second side of the board support member facing the first side;
a coupling section configured to couple the first support member and the second support member such that an interval between the first support member and the second support member is adjustable; and
a held section held by the conveyance jig.

In the first board support member attachment, the first support member and the second support member are coupled to each other such that widths of both the first support member and the second support member can be changed. Therefore, the board support member can be attached to a conveyance member via the board support member attachment regardless of a width of the board.

An assembly jig according to the present disclosure is an assembly jig for a board support member attachment attached to a board support member configured to support a board when the board support member is held by a pair of holding sections, which face each other, of a conveyance jig and conveyed to a board work machine, the board support member attachment including a first support member attached to a first side of the board support member, a second support member attached to a second side of the board support member facing the first side, a first coupling member that couples a first end portion of the first support member and a first end portion of the second support member and in which a first held section held by a first holding section of the pair of holding sections in the conveyance jig is formed, and a second coupling member that couples a second end portion of the first support member and a second end portion of the second support member and in which a second held section held by a second holding section of the pair of holding sections in the conveyance jig is formed, the assembly jig comprising:
a first positioning member configured to detachably hold the first coupling member such that the first held section is positioned at a first position at which the first held section is held by the first holding section;
a second positioning member configured to detachably hold the second coupling member such that the second held section is positioned at a second position at which the second held section is held by the second holding section;
a first moving section configured to support the first support member such that the first support member is parallel to a center line passing through the first position and the second position and configured to move the first support member in an orthogonal direction orthogonal to the center line; and
a second moving section configured to support the second support member such that the second support member is parallel to the center line on a side opposite to the first moving section with respect to the center line and configured to move the second support member in the orthogonal direction orthogonal to the center line.

In the assembly jig, the board support member attachment is assembled as follows. That is, first, a distance from the center line to the first moving section and a distance from the center line to the second moving section are set to widths corresponding to a width of the board support member in the orthogonal direction. In this state, the first and second support members are held by the assembly jig. Then, the first and second held sections are held by the first and second positioning members, the first end portions of the first and second support members are coupled to each other by the first coupling member, and the second end portions of the first and second support members are coupled to each other by the second coupling member. Accordingly, a center position of the held section and a center position of the board support member in the orthogonal direction can be aligned with each other. Therefore, the board support member can be held by the conveyance jig in a stable state.

A second board support member attachment according to the present disclosure is a board support member attachment attached to a board support member configured to support a board when the board support member is held by a pair of holding sections, which face each other, of a conveyance jig and conveyed to a board work machine, the board support member attachment comprising:
a first support member attached to a first side of the board support member;
a second support member attached to a second side of the board support member facing the first side;
a third support member attached between the first support member and the second support member and extending along an extending direction of the first support member and the second support member; and
a pair of held sections provided at both end portions of the third support member in the extending direction and held by the pair of holding sections of the conveyance jig.

In the second board support member attachment, the first to third support members can be attached to the board support member at positions corresponding to a width of a board member. Therefore, the board support member can be attached to a conveyance member via the board support member attachment regardless of a width of the board.

### BRIEF DESCRIPTION OF DRAWINGS

FIG. 1 is a schematic configuration diagram of work device 10.

FIG. 2 is a perspective view showing an internal configuration of work device 10.

FIG. 3 is a side view showing the internal configuration of work device 10.

FIG. 4 is a perspective view of conveyance jig 70.

FIG. 5A is a perspective view showing a state in which board support member attachment 90 is attached to board support member 80 having a narrow width.

FIG. 5B is a perspective view showing a state in which board support member attachment 90 is attached to board support member 80 having a wide width.

FIG. 5C is a perspective view of board support member 80 to which board support member attachment 90 is attached when viewed from a lower surface side.

FIG. 6A is a bottom view showing a state in which first engagement member 74 and second engagement member 76 engage with first pin member 93a and second pin member 94a in a correct orientation.

FIG. 6B is a side view showing a state in which first engagement member 74 and second engagement member 76 engage with first pin member 93a and second pin member 94a in the correct orientation.

FIG. 7A is a bottom view showing a state in which first engagement member 74 and second engagement member 76 engage with first pin member 93a and second pin member 94a in an incorrect orientation.

FIG. 7B is a side view showing a state in which first engagement member 74 and second engagement member 76 engage with first pin member 93a and second pin member 94a in the incorrect orientation.

FIG. 8 is a perspective view showing a schematic configuration of assembly jig 110.

FIG. 9A is a perspective view of first positioning member 112.

FIG. 9B is a perspective view of second positioning member 113.

FIG. 10 is a flowchart showing an example of a procedure for attaching a board support member attachment.

FIG. 11A is a view showing a state in which board support member 80 is placed on loading plate 111 of assembly jig 110.

FIG. 11B is a view showing a state in which first coupling member 93 and second coupling member 94 are placed on board support member 80.

FIG. 11C is a view showing a state in which first attachment member 91 and second attachment member 92 are placed on board support member 80.

FIG. 11D is a view showing a state in which first rail members 91b and 92b are coupled to each other by first coupling member 93 and second rail members 91c and 92c are coupled to each other by second coupling member 94.

FIG. 12A is a perspective view of board support member 80 to which board support member attachment 190 is attached when viewed from an upper surface side.

FIG. 12B is a perspective view of board support member 80 to which board support member attachment 190 is attached when viewed from a lower surface side.

FIG. 13 is a flowchart showing a procedure for attaching a board support member attachment according to a modification example.

FIG. 14A is view showing a modification example in a state in which first rail members 91b and 92b are coupled to each other by first coupling member 93 and second rail members 91c and 92c are coupled to each other by second coupling member 94.

FIG. 14B is an enlarged view of attached sections 91f and 92f in a state in which second coupling member 94 is removed.

### DESCRIPTION OF EMBODIMENTS

Next, an embodiment of the present disclosure will be described with reference to the accompanying drawings.

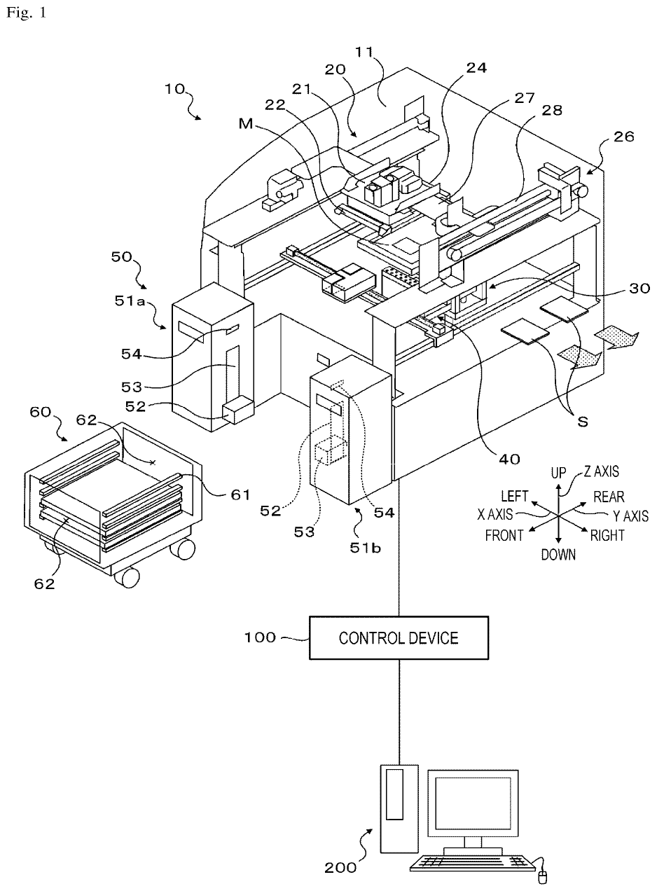

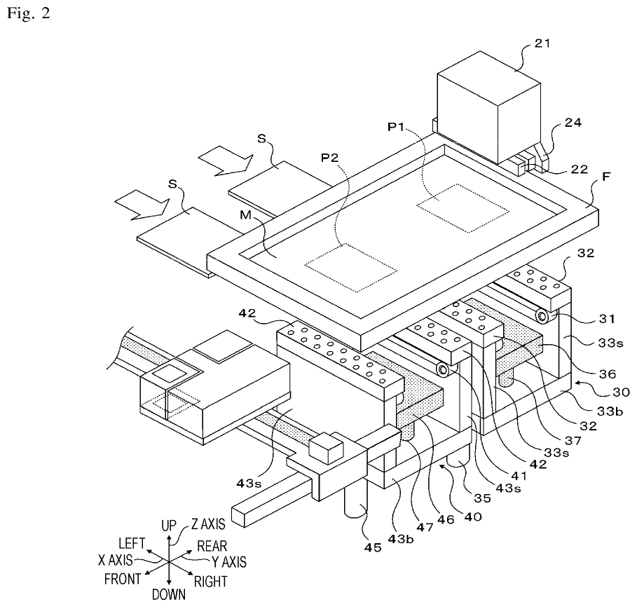

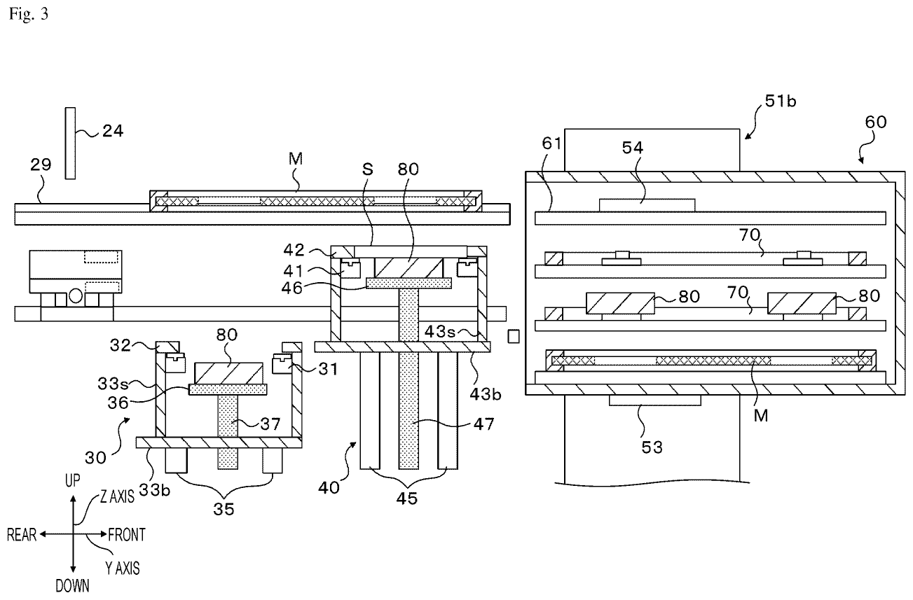

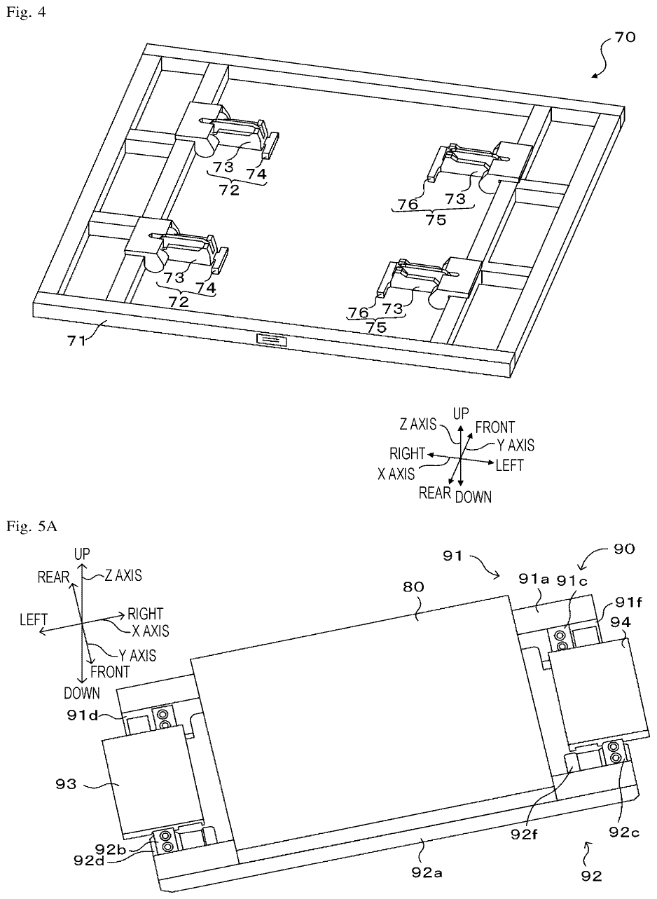

FIG. 1 is a schematic configuration diagram of work device 10. FIG. 2 is a perspective view showing an internal configuration of work device 10. FIG. 3 is a side view showing the internal configuration of work device 10. FIG. 4 is a perspective view of conveyance jig 70. In FIGS. 1 to 4, a left-right direction is referred to as an X axis, a front-rear direction is referred to as a Y axis, and an up-down direction is referred to as a Z axis.

Work device 10 performs predetermined work on board S supported by board support member 80. In the present embodiment, work device 10 is configured as a printing device that, as the predetermined work, applies (prints) a solder paste on board S below via pattern holes P1 and P2 by pressing the solder paste on screen mask M into pattern holes P1 and P2 formed in screen mask M using squeegee 22. Work device 10 constitutes a component mounting system in combination with a mounting device that mounts an electronic component on board S on which solder is printed. Further, work device 10 is capable of automatically exchanging screen mask M or automatically exchanging board support member 80 using conveyance jig 70 when changeover for changing a printing target to a different type of board S is performed.

As shown in FIGS. 1 to 3, work device 10 includes work device main body 11, exchanging device 50, accommodation rack 60, and control device 100. Work device main body 11 includes head device 20 including head 21, support rails 29 that support screen mask M and conveyance jig 70, and first and second board conveyance and support devices 30 and 40 that convey and support board S with dual lanes. In addition, work device 10 also includes an operation panel that is installed in front of work device main body 11, displays various information, and allows various input operations of a worker.

Head device 20 is installed in an upper stage of work device main body 11. As shown in FIG. 1, head device 20 includes head 21 and head moving device 26 that moves head 21 in the front-rear direction (Y-axis direction) that is a printing direction. Head moving device 26 includes Y-axis slider 27 that moves along guide rail 28 extending in the front-rear direction, and a motor that drives Y-axis slider 27. Head 21 includes squeegee 22, a squeegee lifting and lowering device for lifting and lowering squeegee 22 by, for example, an air cylinder, pusher 24, and a pusher lifting and lowering device for lifting and lowering pusher 24 by, for example, an air cylinder. Squeegee 22 is a plate-shaped member extending in the left-right direction (X-axis direction) orthogonal to the printing direction. Pusher 24 is moved back and forth by head moving device 26 in a state in which pusher 24 is lowered by pusher lifting and lowering device 25 and protrudes downward, so that pusher 24 presses screen mask M and conveyance jig 70 on support rails 29 back and forth to convey screen mask M and conveyance jig 70. In addition, when board support member 80 is exchanged using conveyance jig 70, pusher 24 is also used to collect board support member 80 on tables 36 and 46 to conveyance jig 70 conveyed onto support rails 29, or to take out board support member 80 from conveyance jig 70 conveyed onto support rails 29 in a state of holding board support member 80 and place board support member 80 on tables 36 and 46.

Screen mask M is a metal thin plate, and is fixed to rectangular frame body F with a predetermined tension. Pattern holes P1 and P2 for respectively printing solder on board S conveyed and supported by first and second board conveyance and support devices 30 and 40 are formed in screen mask M.

As shown in FIG. 3, support rails 29 are a pair of left and right rails extending in the front-rear direction (Y-axis direction), and are installed between head device 20 and first and second board conveyance and support devices 30 and 40. Support rails 29 support screen mask M and conveyance jig 70 in a horizontal posture, and guide screen mask M and conveyance jig 70 pressed by pusher 24 such that guide screen mask M and conveyance jig 70 move along the front-rear direction.

First and second board conveyance and support devices 30 and 40 convey in and support board S, and bring supported board S into contact with and separate supported board S from screen mask M on support rails 29. As shown in FIGS. 2 and 3, first and second board conveyance and support devices 30 and 40 include conveyor devices 31 and 41, conveyor interval changing devices, conveyor lifting and lowering devices 35 and 45, tables 36 and 46, and support member lifting and lowering devices 37 and 47. Conveyor devices 31 and 41 include conveyor belts respectively provided on pair of front and rear side frames 33s and 43s, and motors that drive the conveyor belts for rotation. Pair of side frames 33s and 43s is erected on base frames 33b and 43b, and board guides 32 and 42 are provided at upper end portions of pair of side frames 33s and 43s. Conveyor interval changing devices 34 and 44 change (adjust) an interval between the conveyor belts by moving one or both of pair of side frames 33s and 43s close to or away from each other. Accordingly, first and second board conveyance and support devices 30 and 40 can convey and support boards S having different sizes. Conveyor lifting and lowering devices 35 and 45 lift and lower conveyor devices 31 and 41 (conveyor belts) by lifting and lowering support columns supporting base frames 33b and 43b. Tables 36 and 46 are support tables having, on an upper surface, an installation surface on which board support member 80 can be installed. Support member lifting and lowering devices 37 and 47 lift and lower board support members 80 installed on tables 36 and 46 by lifting and lowering support columns supporting tables 36 and 46.

Exchanging device 50 receives accommodation rack 60 accommodating exchange members such as screen mask M and conveyance jig 70, and conveys the exchange members between accommodation rack 60 and work device main body 11. Exchanging device 50 includes left unit 51a installed on a left side on a front surface of work device main body 11 and right unit 51b installed on a right side on the front surface of work device main body 11. Left unit 51a and right unit 51b include rack support member 52 that receives accommodation rack 60 and supports a lower surface of accommodation rack 60 from both left and right sides, and rack lifting and lowering device 53 that lifts and lowers rack support member 52. Rack lifting and lowering device 53 includes, for example, a combination of a ball screw mechanism and a motor, or a linear motor. Accommodation rack 60 supported by rack support member 52 is lifted and lowered together with rack support member 52 by rack lifting and lowering device 53. Further, each of left unit 51a and right unit 51b includes frame front-rear moving device 54 that feeds a frame of the exchange member inside accommodation rack 60 back and forth from both left and right sides by a belt, a roller, or the like.

Accommodation rack 60 is an accommodation body including pairs of left and right support rails 61 in multiple stages in the up-down direction and is capable of accommodating the exchange member in each support rail 61. In addition, openings 62 and 62 are formed on work device main body 11, a front surface, and a rear surface of accommodation rack 60. The exchange member is taken in and out by the worker or the like through opening 62 on a front surface side, and is conveyed in and out by frame front-rear moving device 54 through opening 62 on a rear surface side. In a state in which accommodation rack 60 is received by exchanging device 50, frame front-rear moving device 54 feeds the exchange member that is supported on support rails 61 positioned at substantially the same height as support rails 29 of work device main body 11 by rack lifting and lowering device 53 among support rails 61 in multiple stages of accommodation rack 60, to work device main body 11. In addition, frame front-rear moving device 54 feeds the exchange member supported on support rails 29 of work device main body 11 to support rails 61 of accommodation rack 60 positioned at substantially the same height as support rails 29. Accommodation rack 60 may be conveyed to a receiving position of exchanging device 50 by the worker, or may be mounted on an automated guided vehicle (AGV) and automatically conveyed to the receiving position of exchanging device 50 by the automated guided vehicle.

Conveyance jig 70 is a jig used for conveying in and out board support member 80, and includes rectangular frame body 71, first arm member 72, and second arm member 75 as shown in FIG. 4. First arm member 72 and second arm member 75 are fixed to frame body 71 such that distal end portions thereof face each other, and hold board support member 80 from both sides. First arm member 72 includes arm main body 73 and first engagement member 74 provided at a distal end portion of arm main body 73 and engaging with first pin member 93a of board support member attachment 90, which is to be described later, attached to board support member 80. Second arm member 75 includes arm main body 73 and second engagement member 76 provided at the distal end portion of arm main body 73 and engaging with second pin member 94a of board support member attachment 90. First arm member 72 and second arm member 75 are normally biased upward by a spring (not shown), and are in a first state of being horizontally maintained to face each other. Then, when first arm member 72 and second arm member 75 are pressed down from above, first arm member 72 and second arm member 75 rotate against an elastic force of the spring, so that a second state in which first arm member 72 and second arm member 75 are expanded downward is obtained. First arm member 72 and second arm member 75 hold board support member 80 in the first state, and release the holding of board support member 80 in the second state. First arm member 72 and second arm member 75 are pressed down by pusher 24. In the present embodiment, conveyance jig 70 includes two pairs of first arm member 72 and second arm member 75 that hold board support members 80, and each pair can convey board support members 80 used in first and second board conveyance and support devices 30 and 40 at a time.

Board support member 80 supports board S from a lower surface side, and is exchanged, according to board S, with a member having a size suitable for supporting board S. Board support member 80 is used with board support member attachment 90 attached thereto. Board support member attachment 90 is assembled using assembly jig 110 described later.

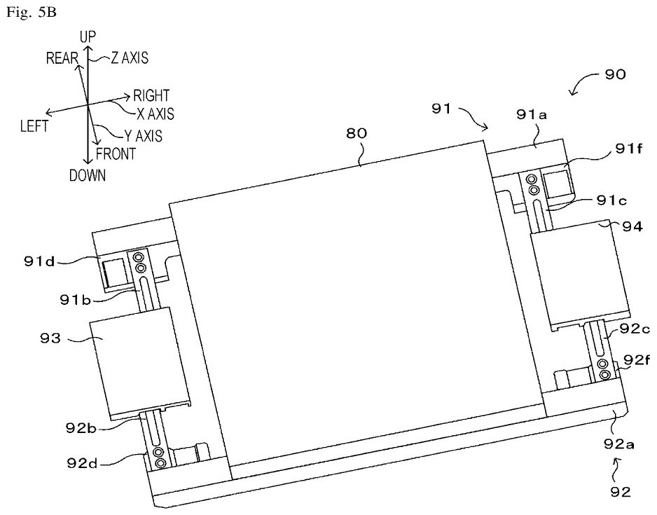

Board support member attachment 90 is for attaching board support member 80 to conveyance jig 70. As shown in FIGS. 5A to 5C, board support member attachment 90 includes first attachment member 91, second attachment member 92, first coupling member 93, second coupling member 94, pair of first pin members 93a, and pair of second pin members 94a.

As shown in FIGS. 5A to 5C, first attachment member 91 is a member attached to a side on a rear side of board support member 80. First attachment member 91 includes first attachment member main body 91a, first rail member 91b, and second rail member 91c. First attachment member main body 91a is a member extending in the left-right direction (X-axis direction). Attached section 91d extending in the front-rear direction (Y-axis direction) is integrally formed at a left end portion (first end portion) of first attachment member main body 91a. Attached section 91f extending in the front-rear direction is integrally formed at a right end portion (second end portion) of first attachment member main body 91a. Attached sections 91d and 91f are formed one step lower than a surface of first attachment member 91 that comes into contact with board support member 80. A base end portion of first rail member 91b is fixed to an upper surface of attached section 91d with a bolt. First rail member 91b extends in the front-rear direction (Y-axis direction orthogonal to first attachment member main body 91a). A base end portion of second rail member 91c is fixed to an upper surface of attached section 91f with a bolt. Second rail member 91c extends in the front-rear direction and in the same direction as first rail member 91b. Elongated hole L11 extending in a longitudinal direction (front-rear direction) is formed in first rail member 91b. Elongated hole L12 extending in the longitudinal direction (front-rear direction) is formed in second rail member 91c.

Second attachment member 92 is a member attached to a side on a front side of board support member 80. Second attachment member 92 includes second attachment member main body 92a, first rail member 92b, and second rail member 92c. Second attachment member main body 92a is a member having substantially the same dimension as first attachment member main body 91a and extending in the left-right direction (X-axis direction). Attached section 92d extending in the front-rear direction (Y-axis direction) is integrally formed at a left end portion (first end portion) of second attachment member main body 92a. Attached section 92f extending in the front-rear direction is integrally formed at a right end portion (second end portion) of second attachment member main body 92a. Attached sections 92d and 92f are formed one step lower than a surface of second attachment member 92 that comes into contact with board support member 80. First rail member 92b is fixed with a bolt to an upper surface of attached section 92d at a position displaced in the left-right direction from a position where first rail member 91b is fixed to attached section 91d. Second rail member 92c extends in the front-rear direction (Y-axis direction orthogonal to second attachment member main body 92a). Second rail member 92c is fixed with a bolt to an upper surface of attached section 92f at a position displaced in the left-right direction from a position where second rail member 91c is fixed to attached section 91f. Second rail member 92c extends in the front-rear direction and in the same direction as first rail member 92b. Elongated hole L21 extending in the longitudinal direction (front-rear direction) is formed in first rail member 92b. Elongated hole L22 extending in the longitudinal direction (front-rear direction) is formed in second rail member 92c.

First coupling member 93 connects first rail member 91b of first attachment member 91 and first rail member 92b of second attachment member 92. On a lower surface of first coupling member 93, long groove G11 that extends in the front-rear direction (Y-axis direction) and into which first rail member 91b of first attachment member 91 can be fitted and long groove G21 that extends in the front-rear direction and into which first rail member 92b of second attachment member 92 can be fitted are formed side by side in the left-right direction (Y-axis direction). As shown in FIG. 5C, multiple screw holes H11 are provided at regular intervals on a bottom surface of long groove G11. Multiple screw holes H21 are provided at regular intervals on a bottom surface of long groove G21. In a state in which first rail member 91b of first attachment member 91 is fitted into long groove G11 and first rail member 92b of second attachment member 92 is fitted into long groove G21, first coupling member 93 couples first rail member 91b of first attachment member 91 and first rail member 92b of second attachment member 92 to each other by inserting screw B into elongated hole L11, tightening screw B into screw hole H11, inserting screw B into elongated hole L21, and tightening screw B into screw hole H21.

Second coupling member 94 couples second rail member 91c of first attachment member 91 and second rail member 92c of second attachment member 92 to each other. On a lower surface of second coupling member 94, long groove G12 that extends in the front-rear direction and into which second rail member 91c of first attachment member 91 can be fitted and long groove G22 that extends in the front-rear direction and into which second rail member 92c of second attachment member 92 can be fitted are formed side by side in the left-right direction. As shown in FIG. 5C, multiple screw holes H12 are provided at regular intervals on a bottom surface of long groove G12. Multiple screw holes H22 are provided at regular intervals on a bottom surface of long groove G22. In a state in which second rail member 91c of first attachment member 91 is fitted into long groove G21 and second rail member 92c of second attachment member 92 is fitted into long groove G22, second coupling member 94 couples second rail member 91c of first attachment member 91 and second rail member 92c of second attachment member 92 to each other by inserting screw B into elongated hole L11, tightening screw B into screw hole H11, inserting screw B into elongated hole L21, and tightening screw B into screw hole H21.

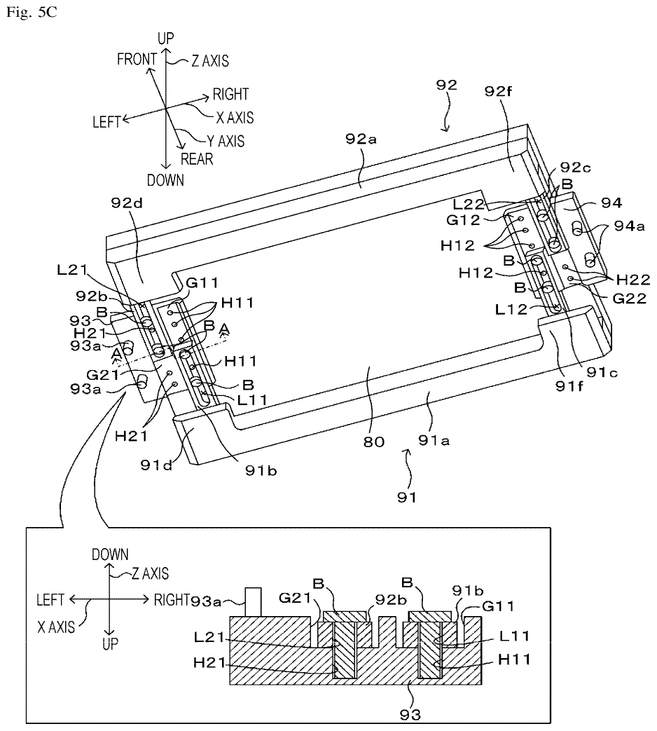

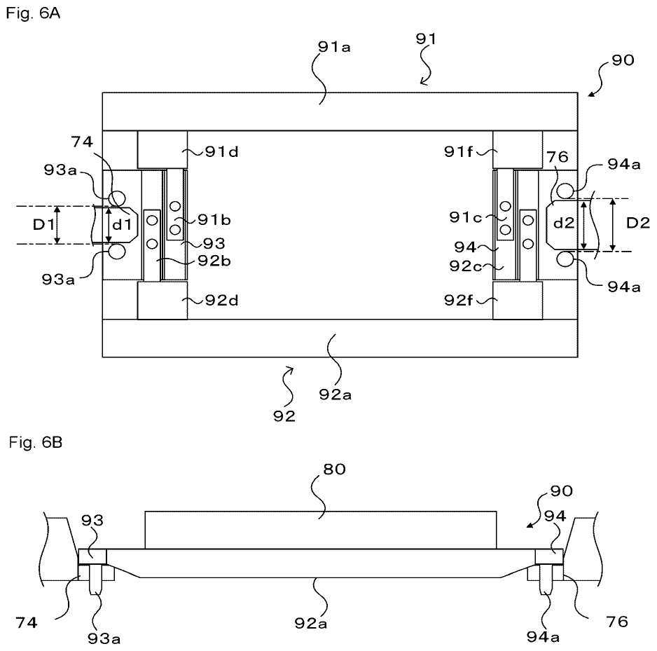

Pair of first pin members 93a are engaged sections that engages with first engagement member 74 of first arm member 72, which is a first one of the pair of arm members of conveyance jig 70. Pair of first pin members 93a are provided on the lower surface of first coupling member 93 such that a center in the front-rear direction (Y-axis direction) coincides with a center of first coupling member 93 in the front-rear direction. Width D1 between pair of first pin members 93a in the front-rear direction (refer to FIG. 6A) is slightly larger than width d1 of first engagement member 74 in the front-rear direction. Pair of first pin members 93a engages with first engagement member 74 by first engagement member 74 fitting therebetween.

Pair of second pin members 94a are engaged sections that engages with second engagement member 76 of second arm member 75, which is a second one of the pair of arm members of conveyance jig 70. Pair of second pin members 94a are provided on the lower surface of second coupling member 94 such that a center in the front-rear direction (Y-axis direction) coincides with a center of second coupling member 94 in the front-rear direction. Width D2 (D2>D1) between pair of second pin members 94a in the front-rear direction (refer to FIG. 6A) is slightly larger than width d2 of second engagement member 76 in the front-rear direction. Pair of second pin members 94a engages with second engagement member 76 by second engagement member 76 fitting therebetween.

In board support member attachment 90, in a state in which first attachment member 91 and second attachment member 92 are brought close to each other in the front-rear direction, first rail member 91b of first attachment member 91 and first rail member 92b of second attachment member 92 can be coupled to each other by first coupling member 93, and second rail member 91c of first attachment member 91 and second rail member 92c of second attachment member 92 can be coupled to each other by second coupling member 94. Further, in a state in which first attachment member 91 and second attachment member 92 are separated from each other in the front-rear direction, first rail member 91b of first attachment member 91 and first rail member 92b of second attachment member 92 can be coupled to each other by first coupling member 93, and second rail member 91c of first attachment member 91 and second rail member 92c of second attachment member 92 can be coupled to each other by second coupling member 94. As described above, in board support member attachment 90, since the interval between first attachment member 91 and second attachment member 92 can be adjusted, board support member 80 can be attached to conveyance jig 70 via board support member attachment 90 regardless of a width of board S.

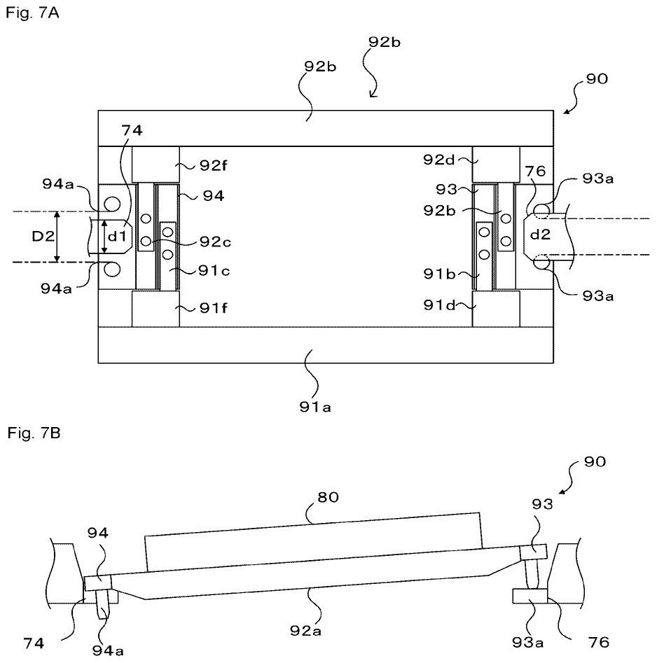

As shown in FIG. 6A, width d1 of first engagement member 74 is smaller than width d2 of second engagement member 76, and interval DI between pair of first pin members 93a held by first engagement member 74 is smaller than interval D2 between pair of second pin members 94a with which second engagement member 76 engages. Accordingly, as shown in FIG. 6B, board support member 80 is held in a horizontal posture when right and left sides of board support member 80 are attached to conveyance jig 70 in a correct direction. On the other hand, as shown in FIGS. 7A and 7B, when board support member 80 is attached to conveyance jig 70 with the left and right sides reversed by 180 degrees, second engagement member 76 having width d2 larger than interval D1 between first pin members 93a does not normally engage between first pin members 93a, and thus board support member 80 is held in a state of being inclined with respect to conveyance jig 70. Accordingly, the worker can be made aware that board support member 80 has been attached in a wrong direction. Width d1 of first engagement member 74 is smaller than the smallest width of board support members 80 usable in work device 10.

Control device 100 is configured as a microprocessor mainly including CPU, and includes ROM, RAM, an input/output port, and the like in addition to the CPU. Control device 100 exchanges signals with head device 20, first and second board conveyance and support devices 30 and 40, exchanging device 50, and the like. In addition, control device 100 is communicably connected to management device 200 that manages an entire work system including work device 10. Management device 200 manages a progress state and the like of a line including work device 10.

An operation of work device 10 configured as described above will be described. In the present embodiment, a changeover operation for exchanging screen mask M and board support member 80 will be described. The changeover is performed by executing a mask convey-out process, a support member convey-out process, a support member convey-in process, and a mask convey-in process in this order in a state in which accommodation rack 60 is set in exchanging device 50.

The mask convey-out process is a process of conveying out used screen mask M from work device main body 11 and accommodating screen mask M in accommodation rack 60. In the mask convey-out process, control device 100 controls rack lifting and lowering device 53 such that empty support rails 61 of accommodation rack 60 are at substantially the same height as support rails 29 of work device main body 11. Subsequently, control device 100 controls head moving device 26 such that screen mask M supported by support rail 29 is pressed forward by pusher 24 and conveyed out from work device main body 11. Then, control device 100 controls frame front-rear moving device 54 such that conveyed screen mask M is accommodated in accommodation rack 60. The mask convey-in process is a process of taking out screen mask M to be used next from accommodation rack 60 and conveying screen mask M into work device main body 11. Since the mask convey-in process is basically executed by an operation reverse to the mask convey-out process, a description thereof will be omitted.

In the support member convey-out process, used board support member 80 is conveyed out from work device main body 11 and accommodated in accommodation rack 60. First, control device 100 controls rack lifting and lowering device 53 such that support rails 61 of accommodation rack 60 that support empty conveyance jig 70 used for collecting board support member 80 are at substantially the same height as support rails 29 of work device main body 11. Subsequently, control device 100 controls frame front-rear moving device 54 such that empty conveyance jig 70 is conveyed from accommodation rack 60 into work device main body 11, and controls the pusher lifting and lowering device and head moving device 26 such that conveyed empty conveyance jig 70 moves to a space above tables 36 and 46 by pusher 24. Next, control device 100 controls head moving device 26 such that pusher 24 moves to a space directly above first arm member 72 and second arm member 75 of empty conveyance jig 70. Subsequently, control device 100 controls pusher lifting and lowering device 25 such that pusher 24 is lowered. As described above, when pusher 24 is lowered, pusher 24 comes into contact with first arm member 72 and second arm member 75, and when pusher 24 is further lowered, pair of first arm member 72 and second arm member 75 is expanded downward and a state (second state) in which board support member 80 can be received is obtained. Next, control device 100 controls support member lifting and lowering device 37 or support member lifting and lowering device 47 such that table 36 or table 46 is lifted. Then, control device 100 controls pusher lifting and lowering device 25 such that pusher 24 is lifted. Accordingly, first arm member 72 and second arm member 75 are in the first state of facing each other, and board support member 80 is held by conveyance jig 70 (first arm member 72 and second arm member 75). Control device 100 causes conveyance jig 70 to hold board support member 80 placed on a second one of table 36 and table 46 by the same control.

Next, control device 100 controls rack lifting and lowering device 53 such that accommodation rack 60 is lifted until empty support rails 61 of accommodation rack 60 are at substantially the same height as support rails 29 of work device main body 11. Then, control device 100 controls head moving device 26 such that pusher 24 is lowered by pusher lifting and lowering device 25 and conveyance jig 70 on support rails 29 is pressed forward by pusher 24 and conveyed out. Then, control device 100 controls frame front-rear moving device 54 such that board support member 80 held by conveyance jig 70 is conveyed to accommodation rack 60.

The support member convey-in process is a process of taking out board support member 80 to be used next from accommodation rack 60 and conveying board support member 80 into work device main body 11. In the support member convey-in process, conveyance jig 70 holding two board support members 80 is conveyed into work device main body 11, and conveyance jig 70 is controlled such that conveyance jig 70 is moved to a space above table 36 or table 46 by pusher 24. Subsequently, control device 100 performs control such that table 36 or table 46 is lifted, and then performs control such that pusher 24 is lowered directly above first arm member 72 and second arm member 75 of conveyance jig 70 holding a first one of two board support members 80. As a result, pair of first arm member 72 and second arm member 75 is expanded downward (second state), and board support member 80 is detached from pair of first arm member 72 and second arm member 75 and placed on table 36 or table 46. Control device 100 places a second one of board support members 80 held by conveyance jig 70 on a second one of the tables by the same control. Then, control device 100 performs control such that table 36 and table 46 are lowered, and performs control such that empty conveyance jig 70 from which two board support members 80 are taken out is conveyed out from work device main body 11 and accommodated in accommodation rack 60.

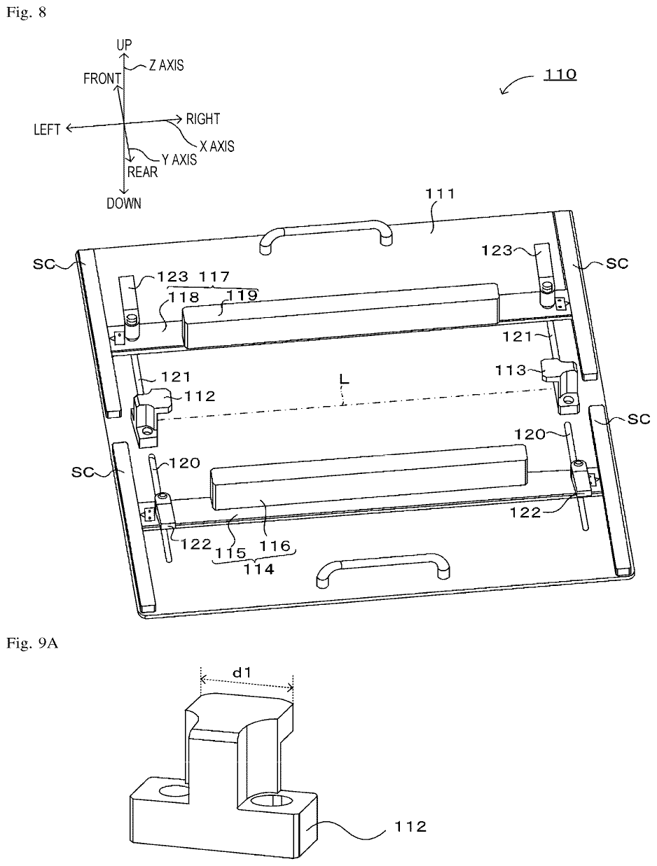

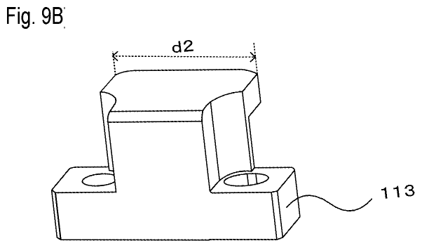

Next, a procedure for attaching board support member attachment 90 to board support member 80 will be described with reference to FIGS. 8 to 11D. First, details of assembly jig 110 used for assembling board support member attachment 90 will be described with reference to FIGS. 8, 9A, and 9B.

Assembly jig 110 includes first positioning member 112, second positioning member 113, first moving section 114, second moving section 117, first clamp mechanism 122, and second clamp mechanism 123. These components are provided on loading plate 111.

Pair of left and right elongated holes 120 extending in the front-rear direction (Y-axis direction) are formed on rear sides of both end portions of loading plate 111 in the left-right direction. Scale SC indicating a position of first moving section 114 on loading plate 111 is provided outside pair of elongated holes 120 in the left-right direction (X-axis direction). Pair of left and right elongated holes 121 extending in the front-rear direction are formed on front sides of both end portions of loading plate 111 in the left-right direction. Scale SC indicating a position of second moving section 117 on loading plate 111 is provided outside pair of elongated holes 121 in the left-right direction. A distance from center line L, which is described later, connecting a center of first positioning member 112 in the front-rear direction and a center of second positioning member 113 in the front-rear direction is given to scale SC. Note that the distance corresponds to the width of board support member 80, to which board support member attachment 90 is attached, in the front-rear direction, and is, for example, half the width of board support member 80 in the front-rear direction.

First positioning member 112 is used to position first coupling member 93 when board support member attachment 90 is assembled. First positioning member 112 is detachably attached to a substantially center of loading plate 111 in the front-rear direction and a left end side of loading plate 111 with a screw or the like. As shown in FIG. 9A, a width of first positioning member 112 in the front-rear direction is the same width (width d1) as the width of first engagement member 74 in the front-rear direction. First positioning member 112 is attached to loading plate 111 in a state of being fitted between pair of first pin members 93a of first coupling member 93, thereby positioning first coupling member 93.

Second positioning member 113 is used to position second coupling member 94 when board support member attachment 90 is assembled. Second positioning member 113 is detachably attached to a substantially center of loading plate 111 in the front-rear direction and a right end side of loading plate 111 with a screw or the like. As shown in FIG. 9B, a width of second positioning member 113 in the front-rear direction is the same width (width d2) as the width of second engagement member 76 in the front-rear direction. Second positioning member 113 is attached to loading plate 111 in a state of being fitted between pair of second pin members 94a of second coupling member 94, thereby positioning second coupling member 94.

First moving section 114 supports first attachment member 91 when board support member attachment 90 is assembled. First moving section 114 is provided on a rear side of loading plate 111 in the front-rear direction (Y-axis direction). First moving section 114 includes first slider 115 movable back and forth along elongated hole 120, and first block 116 fixed to an upper surface of first slider 115. First moving section 114 supports first attachment member 91 by causing first attachment member 91 to abut a front side surface of first block 116.

Second moving section 117 supports second attachment member 92 when board support member attachment 90 is assembled. Second moving section 117 is provided on a front side of loading plate 111 in the front-rear direction (Y-axis direction). Second moving section 117 includes second slider 118 movable back and forth along elongated hole 121, and second block 119 fixed to an upper surface of second slider 118. Second moving section 117 supports second attachment member 92 by causing second attachment member 92 to abut a rear side surface of second block 119.

First clamp mechanism 122 fixes first moving section 114 at any position within a moving range. First clamp mechanism 122 includes a clamp screw that penetrates elongated hole 120 in the up-down direction, a screw receiver that is provided on a lower surface of loading plate 111 and is movable back and forth together with first slider 115, and a clamp lever that tightens and loosens the screw with respect to the screw receiver. In first clamp mechanism 122, when the clamp lever is operated to loosen the screw with respect to the screw receiver, first slider 115 is allowed to move back and forth. On the other hand, in first clamp mechanism 122, when the clamp lever is operated to tighten the screw with respect to the screw receiver, first slider 115 is restricted from moving back and forth.

Second clamp mechanism 123 fixes second moving section 117 at any position within the moving range. Second clamp mechanism 123 includes a clamp screw that penetrates elongated hole 121 in the up-down direction, a screw receiver that is provided on the lower surface of loading plate 111 and is movable back and forth together with second slider 118, and a clamp lever that tightens and loosens the screw with respect to the screw receiver. In second clamp mechanism 123, when the clamp lever is operated to loosen the screw with respect to the screw receiver, second slider 118 is allowed to move back and forth. On the other hand, in second clamp mechanism 123, when the clamp lever is operated to tighten the screw with respect to the screw receiver, second slider 118 is restricted from moving back and forth.

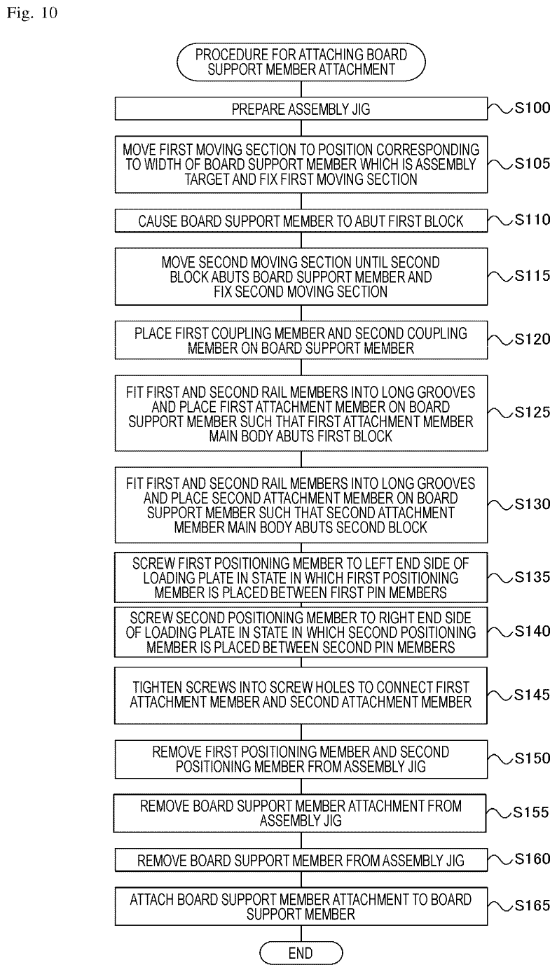

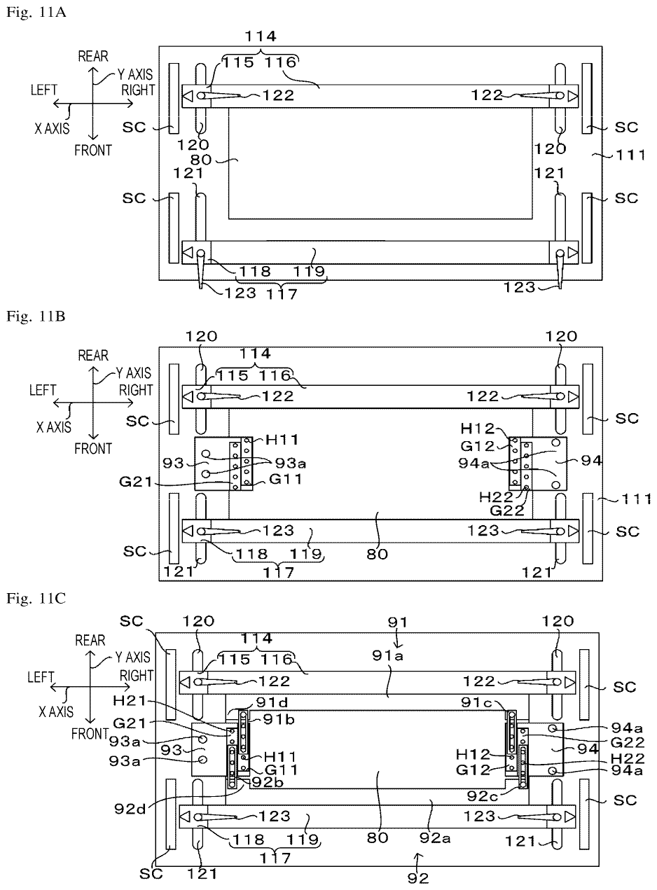

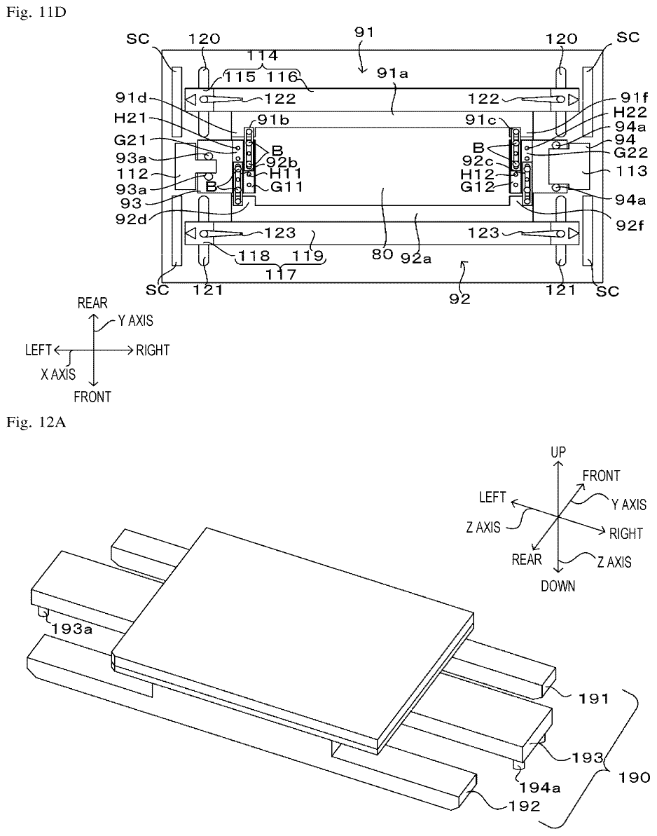

Next, a procedure of attaching board support member attachment 90 to board support member 80 will be described with reference to FIGS. 10 to 11D. First, the worker prepares assembly jig 110 (S100). Next, as shown in FIG. 11A, the worker moves first moving section 114 to a position corresponding to the width of board support member 80, to which board support member attachment 90 is attached, in the front-rear direction (Y-axis direction) while viewing scale SC, and operates first clamp mechanism 122 to fix first moving section 114 at the position (S105). In this case, a distance from center line L to first moving section 114 (first block 116) is half the width of board support member 80, to which board support member attachment 90 is attached, in the front-rear direction. Subsequently, the worker places board support member 80 on loading plate 111 such that a rear side surface of board support member 80 abuts the front side surface of first block 116 of first moving section 114 (S110). Then, the worker moves second moving section 117 until the rear side surface of second block 119 abuts the front side surface of board support member 80, and operates second clamp mechanism 123 to fix second moving section 117 at the position (S115). In this case, a distance from center line L to second moving section 117 (second block 119) is half the width of board support member 80, to which board support member attachment 90 is attached, in the front-rear direction. The worker checks scale SC indicating the position of first moving section 114 and checks scale SC indicating the position of second moving section 117, and when the two do not coincides with each other, the worker finely adjusts the positions of first moving section 114 and second moving section 117 with respect to loading plate 111.

Next, the worker places first coupling member 93 at a left end on board support member 80 with first pin member 93a facing upward, and places second coupling member 94 at a right end on board support member 80 with second pin member 94a facing upward (S120). Subsequently, as shown in FIG. 11C, the worker fits first rail member 91b and second rail member 91c of first attachment member 91 into long groove G11 of first coupling member 93 and long groove G12 of second coupling member 94, respectively, and places first attachment member 91 on board support member 80 such that a side surface of first attachment member main body 91a abuts first block 116 (S125). Then, as shown in FIG. 11C, the worker fits first rail member 92b and second rail member 92c of second attachment member 92 into long groove G21 of first coupling member 93 and long groove G22 of second coupling member 94, respectively, and places second attachment member 92 on board support member 80 such that a side surface of second attachment member main body 92a abuts second block 119 (S130).

Next, as shown in FIG. 11C, the worker screws (fixes) first positioning member 112 to the left end side of loading plate 111 in a state in which first positioning member 112 is sandwiched between pair of first pin members 93a (S135). Subsequently, as shown in FIG. 11C, the worker screws (fixes) second positioning member 113 to the right end side of loading plate 111 in a state in which second positioning member 113 is sandwiched between pair of second pin members 94a (S140). Then, the worker connects first attachment member 91 and second attachment member 92 to each other by inserting screw B into elongated hole L11 and tightening screw B into screw hole H11, inserting screw B into elongated hole L21 and tightening screw B into screw hole H21, inserting screw B into elongated hole L12 and tightening screw B into screw hole H12, and inserting screw B into elongated hole L22 and tightening screw B into screw hole H22 (S145). Accordingly, first attachment member 91 and second attachment member 92 can be coupled to each other in a state in which the center of pair of first pin members 93a in the front-rear direction coincides with the center of pair of second pin members 94a in the front-rear direction.

Next, the worker removes first positioning member 112 and second positioning member 113 from assembly jig 110 (S150). Subsequently, the worker removes board support member attachment 90 from assembly jig 110 (S155). Next, the worker removes board support member 80 from assembly jig 110 (S160). Then, the worker assembles board support member attachment 90 to board support member 80 with a screw or the like (S165), and ends the procedure.

In assembly jig 110, the center of pair of first pin members 93a in the front-rear direction can be assembled with board support member attachment 90 of pair of second pin members 94a. Therefore, board support member 80 can be held by conveyance jig 70 in a stable state.

Here, a correspondence relationship between elements of the embodiment and elements of the present disclosure will be described. That is, board support member attachment 90 of the present embodiment corresponds to a first board support member attachment of the present disclosure, first attachment member 91 corresponds to a first support member, second attachment member 92 corresponds to a second support member, first coupling member 93 and second coupling member 94 correspond to a coupling section, and first pin member 93a and second pin member 94a correspond to a held section. First attachment member main body 91a corresponds to a first support member main body, first rail member 91b and second rail member 91c correspond to a first extending portion, second attachment member main body 92a corresponds to a second support member main body, and first rail member 92b and second rail member 92c correspond to a second extending portion. In addition, assembly jig 110 corresponds to an assembly jig for a board support member attachment, first positioning member 112 corresponds to a first positioning member, second positioning member 113 corresponds to a second positioning member, first moving section 114 corresponds to a first moving section, and second moving section 117 corresponds to a second moving section. Loading plate 111 corresponds to a loading plate, first clamp mechanism 122 corresponds to a first fixing section, and second clamp mechanism 123 corresponds to a second fixing section.

In board support member attachment 90 described in detail above, first attachment member 91 and second attachment member 92 are coupled such that the widths thereof can be changed. Therefore, board support member 80 can be attached to conveyance jig 70 via board support member attachment 90 regardless of the width of board S.

In board support member attachment 90, first attachment member 91 includes first attachment member main body 91a, and first rail member 91b and second rail member 91c extending in the front-rear direction from both left and right end portions of first attachment member main body 91a. Second attachment member 92 includes second attachment member main body 92a, and first rail member 92b and second rail member 92c extending in the front-rear direction from both left and right end portions of second attachment member main body 92a. Further, board support member attachment 90 includes first coupling member 93 that couples first rail member 91b and first rail member 92b, and second coupling member 94 that couples second rail member 91c and second rail member 92c. Accordingly, the widths of first attachment member 91 and second attachment member 92 can be adjusted relatively easily.

In assembly jig 110, the distance from center line L to first moving section 114 and the distance from center line L to second moving section 117 are set to half the width of board support member 80 in the front-rear direction. In this state, first attachment member 91 and second attachment member 92 are supported by assembly jig 110. Then, first pin member 93a and second pin member 94a are held by first positioning member 112 and second positioning member 113, respectively, and first rail member 91b and first rail member 92b are coupled by first coupling member 93, and second rail member 91c and second rail member 92c are coupled by second coupling member 94. Accordingly, a center position of first pin member 93a and second pin member 94a and a center position of board support member 80 in the front-rear direction can be aligned with each other. Therefore, the board support member can be held by the conveyance jig in a stable state.

In addition, assembly jig 110 includes first positioning member 112, second positioning member 113, first clamp mechanism 122 that fixes first moving section 114 at any position within a movable range, and second clamp mechanism 123 that fixes second moving section 117 at any position within the movable range. Accordingly, when the positions of first attachment member 91 and second attachment member 92 are aligned with the positions of first moving section 114 and second moving section 117, respectively, the positions of first moving section 114 and second moving section 117 are less likely to be displaced.

It goes without saying that the present disclosure is not limited to the embodiments described above, and can be implemented in various aspects as long as the aspects fall within the technical scope of the present disclosure.

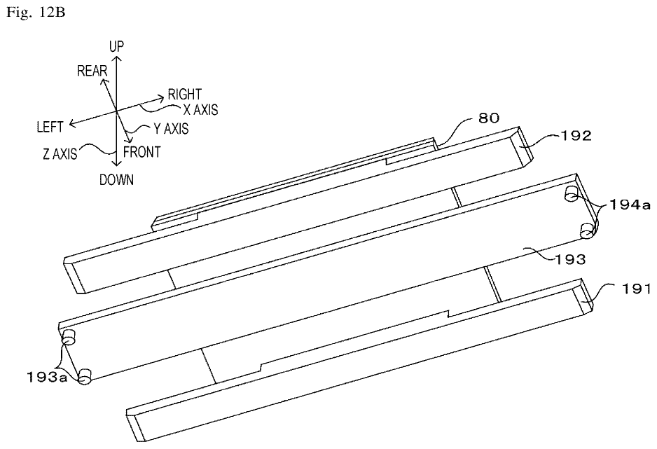

For example, in the above-described embodiment, board support member 80 is held by conveyance jig 70 using the board support member attachment capable of adjusting the interval between first attachment member 91 and second attachment member 92 in the front-rear direction. However, as shown in FIGS. 12A and 12B, board support member 80 may be held by conveyance jig 70 using board support member attachment 190. Board support member attachment 190 includes first attachment member 191 extending in the left-right direction (X-axis direction) and attached to a side on the front side of board support member 80, second attachment member 192 extending in the left-right direction and attached to a side on the rear side of board support member 80, and third attachment member 193 extending in the left-right direction and attached between first attachment member 191 and second attachment member 192. Third attachment member 193 is attached to board support member 80 such that a center thereof in the front-rear direction coincides with the center of board support member 80 in the front-rear direction. Pair of first pin members 193a engaging with first engagement member 74 provided on first arm member 72 of conveyance jig 70 is provided on a left end portion of third attachment member 193. Pair of second pin members 194a engaging with second engagement member 76 provided on second arm member 75 of conveyance jig 70 is provided on a right end portion of third attachment member 193. A width between first pin members 193a in the front-rear direction is a width (width D1) equal to the width between first pin members 93a in board support member attachment 90. A width between second pin members 194a in the front-rear direction is a width (width D2) equal to the width between second pin members 94a in board support member attachment 90. Accordingly, board support member 80 can be attached to conveyance jig 70 via board support member attachment 190 regardless of the width of board S.

In the above-described embodiment, width D1 between first pin members 93a in the front-rear direction is smaller than width D2 between second pin members 94a in the front-rear direction. However, width D1 may be larger than width D2. Alternatively, width D1 may be equal to width D2.

In the above-described embodiment, in the procedure for attaching a board support member attachment, after board support member attachment 90 and board support member 80 are removed from assembly jig 110, board support member attachment 90 is attached to board support member 80. However, in the procedure for attaching a board support member attachment, board support member 80 may be removed from assembly jig 110 together with board support member attachment 90 after board support member attachment 90 is attached to board support member 80.

In the above-described embodiment, the held section of the present disclosure has been described as pair of first pin members 93a and pair of second pin members 94a. However, the held section of the present disclosure may have another configuration. For example, a recessed portion engaging with first engagement member 74 may be used instead of pair of first pin members 93a, or a recessed portion engaging with second engagement member 76 may be used instead of pair of second pin members 94a.

Here, a procedure for attaching a board support member attachment according to a modification example will be described. In the procedure for attaching a board support member attachment according to the modification example, a direction in which first attachment member 91 and second attachment member 92 are placed on board support member 80 may be reversed from the direction in the above-described embodiment. That is, when board support member attachment 90 is attached to board support member 80, first attachment member 91 and second attachment member 92 may be placed on board support member 80 and assembled in a state in which the surfaces of first attachment member 91 and second attachment member 92 that come into contact with board support member 80 face upward. In this case, first rail members 91b and 92b of first and second attachment members 91 and 92 are coupled to each other by first coupling member 93 in a state in which pair of first pin members 93a face downward. Further, second rail members 91c and 92c of first and second attachment members 91 and 92 are coupled to each other by second coupling member 94 in a state in which pair of second pin members 94a face downward.

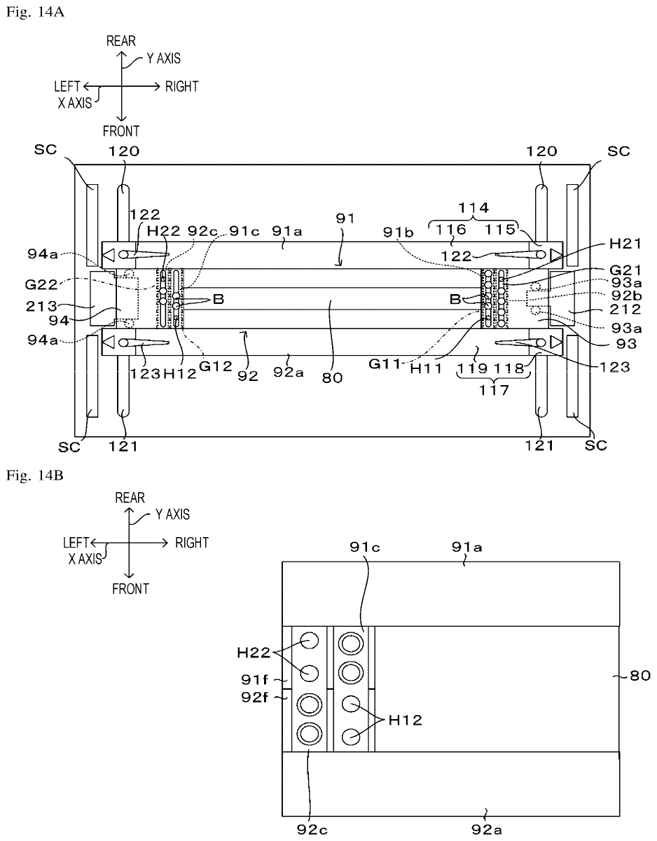

In the procedure for attaching a board support member attachment according to the modification example, the worker screws (fixes) first positioning member 212 and second positioning member 213 to loading plate 111 before placing first attachment member 91 and second attachment member 92 on board support member 80. Then, the worker covers first coupling member 93 from above first rail member 91b of first attachment member 91 and first rail member 92b of second attachment member 92, inserts screw B into each elongated hole, and tightens screw B into each screw hole. In this case, it is desirable that elongated hole L11 and elongated hole L21 are formed on a side of first coupling member 93, screw hole H11 is formed on a side of first rail member 91b of first attachment member 91, and screw hole H21 is formed on a side of first rail member 92b of second attachment member 92. The worker covers second coupling member 94 from above second rail member 91c of first attachment member 91 and second rail member 92c of second attachment member 92, inserts screw B into each elongated hole, and tightens screw B into each screw hole. In this case, it is desirable that elongated hole L12 and elongated hole L22 are formed on a side of second coupling member 94, screw hole H12 is formed on a side of second rail member 92c of first attachment member 91, and screw hole H22 is formed on a side of second rail member 92c of second attachment member 92. This is because, as in the above-described embodiment, when screw holes are formed in first coupling member 93 and second coupling member 94 and elongated holes are formed in first rail members 91b and 92b and second rail members 91c and 92c, it is necessary to tighten screws B from a back side, and it is difficult to couple first attachment member 91 and second attachment member 92. The procedure for attaching a board support member attachment according to the modification example is used to assemble board support member attachment 90 attached to board support member 80 having a relatively short length in the front-rear direction. This is because, when the width of board support member 80 in the front-rear direction is short, when board support member attachment 90 is assembled in the same procedure as in the above-described embodiment, first attachment member 91 and second attachment member 92 cannot be coupled in some cases. As shown in FIGS. 14A and 14B, a case where first attachment member 91 and second attachment member 92 are brought close to each other to the extent that attached sections 91d and 92d abut each other and attached sections 91f and 92f abut each other since board support member attachment 90 is attached to board support member 80 having a short width in the front-rear direction will be considered. In this case, when the surface that comes into contact with board support member 80 when board support member attachment 90 is attached to board support member 80 faces downward, first rail member 91b and second rail member 91c are hidden under attached sections 92d and 92f, respectively, and first rail member 92b and second rail member 92c are hidden under attached sections 91d and 91f, respectively. Therefore, screw B cannot be tightened by the same procedure as in the above-described embodiment.

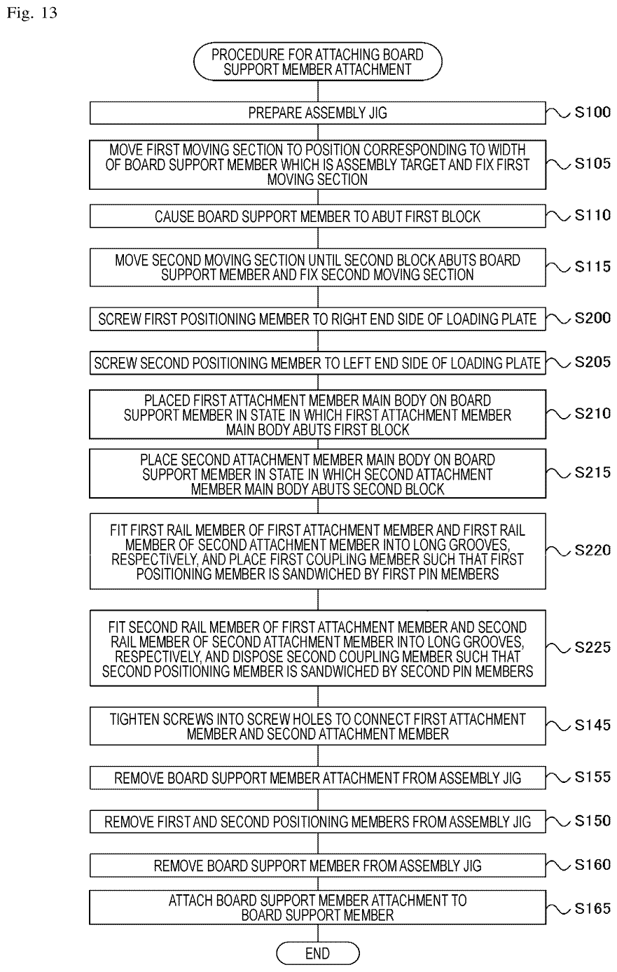

The details of the process will be described with reference to FIGS. 13 and 14. In FIG. 13, the same procedures as those in FIG. 10 are denoted by the same step numbers, and detailed description thereof is omitted.

First, similarly to the above-described embodiment, the worker prepares assembly jig 110, fixes first moving section 114 at a position corresponding to the width of board support member 80, and places board support member 80 on loading plate 111 (S100 to S110). Next, the worker moves second moving section 117 until second block 119 abuts a side surface of board support member 80, and fixes second moving section 117 (S110, S115). Subsequently, as shown in FIG. 14A, the worker screws (fixes) first positioning member 212 to the right end side of loading plate 111 (S200). Then, the worker screws (fixes) second positioning member 213 to the left end side of loading plate 111 (S205). Here, the lengths of first positioning member 212 and second positioning member 213 in the up-down direction are shorter than the lengths of first positioning member 112 and second positioning member 113 in the up-down direction. Next, the worker places first attachment member 91 on board support member 80 with the surface, which comes into contact with board support member 80 when attached to board support member 80, facing upward and the side surface abutting first block 116 (S210). Subsequently, the worker places second attachment member 92 on board support member 80 with the surface, which comes into contact with board support member 80 when attached to board support member 80, facing upward and the side surface abutting second block 119 (S215). Then, with pair of first pin members 93a facing downward, the worker fits first rail member 91b of first attachment member 91 and first rail member 92b of second attachment member 92 into long grooves G11 and G21, respectively, and places first coupling member 93 such that first positioning member 212 is sandwiched by first pin members 93a (S220). Subsequently, with pair of second pin members 94a facing downward, the worker fits second rail member 91c of first attachment member 91 and second rail member 92c of second attachment member 92 into long grooves G12 and G22, respectively, and places second coupling member 94 such that second positioning member 213 is sandwiched by second pin members 94a (S225). Subsequently, the worker couples first attachment member 91 and second attachment member 92 to each other by inserting screw B into each elongated hole and tightening screw B into each screw hole (S145). Next, the worker removes board support member attachment 90, first positioning member 212, second positioning member 213, and board support member 80 from assembly jig 110 in this order (S155, S150, S160). Then, the worker assembles board support member attachment 90 to board support member 80 with a screw or the like (S165), and ends the procedure.

In addition, in the above-described embodiment, work device 10 includes two lanes that convey and support board S, but may include only one lane.

In addition, in the above-described embodiment, the work device of the present disclosure has been described by applying it to a printing device, but the present disclosure is not limited to this, and may be applied to any work device configured to perform work on a board supported by a support member, such as a component mounter, as long as the support member can be automatically exchanged.

### INDUSTRIAL APPLICABILITY

The present disclosure can be used in a manufacturing industry of board support member attachment, an assembly jig, and a printing device.

### REFERENCE SIGNS LIST

10: work device, 11: work device main body, 20: head device, 21: head, 22: squeegee, 23: squeegee lifting and lowering device, 24: pusher, 25: pusher lifting and lowering device, 26: head moving device, 27: Y-axis slider, 28: guide rail, 29: support rail, 30: first board conveyance and support device, 31: conveyor device, 32: board guide, 33b: base frame, 33s: side frame, 35: conveyor lifting and lowering device, 36: table, 37: support member lifting and lowering device, 40: second board conveyance and support device, 41: conveyor device, 42: board guide, 43b: base frame, 43s: side frame, 45: conveyor lifting and lowering device, 46: table, 47: support member lifting and lowering device, 50: exchanging device, 51a: left unit, 51b: right unit, 52: rack support member, 53: rack lifting and lowering device, 54: frame front-rear moving device, 60: accommodation rack, 61: support rail, 62: opening, 70: conveyance jig, 71: frame body, 72: first arm member, 73: arm main body, 74: first engagement member, 75: second arm member, 76: second engagement member, 80: board support member, 90: board support member attachment, 91: first attachment member, 91a: first attachment member main body, 91b: first rail member, 91c: second rail member, 91d, 91f: attached section, 92: second attachment member, 92a: second attachment member main body, 92b: first rail member, 92c: second rail member, 92d, 92f: attached section, 93: first coupling member, 93a: first pin member, 94: second coupling member, 94a: second pin member, 100: control device, 110: assembly jig, 111: loading plate, 112: first positioning member, 113: second positioning member, 114: first moving section, 115: first slider, 116: first block, 117: second moving section, 118: second slider, 119: second block, 120: elongated hole, 121: elongated hole, 122: first clamp mechanism, 123: second clamp mechanism, 190: board support member attachment, 191: first attachment member, 192: second attachment member, 193: third attachment member, 193a: first pin member, 194a: second pin member, 200: management device, 212: first positioning member, 213: second positioning member, B: screw, G11, G12, G21, G22: long groove, H11, H12, H21, H22: screw hole, L: center line, L11, L12, L21, L22: elongated hole, M: screen mask, P1, P2: pattern hole, S: board, SC: scale.

1. A board support member attachment attached to a board support member configured to support a board when the board support member is held by a conveyance jig and conveyed to a board work machine, the board support member attachment comprising:
a first support member attached to a first side of the board support member;
a second support member attached to a second side of the board support member facing the first side;
a coupling section configured to couple the first support member and the second support member such that an interval between the first support member and the second support member is adjustable; and
a held section held by the conveyance jig.

2. The board support member attachment according to claim 1,
wherein the first support member includes a first support member main body, and a pair of first extending portions extending from both end portions of the first support member main body in a direction orthogonal to the first support member main body,
the second support member includes a second support member main body, and a pair of second extending portions extending from both end portions of the second support member main body in a direction orthogonal to the second support member main body, and
the coupling section includes a first coupling member configured to couple a first one of the pair of first extending portions and a first one of the pair of second extending portions, and a second coupling member configured to couple a second one of the pair of first extending portions and a second one of the pair of second extending portions.

3. An assembly jig for a board support member attachment attached to a board support member configured to support a board when the board support member is held by a pair of holding sections, which face each other, of a conveyance jig and conveyed to a board work machine, the board support member attachment including a first support member attached to a first side of the board support member, a second support member attached to a second side of the board support member facing the first side, a first coupling member that couples a first end portion of the first support member and a first end portion of the second support member and in which a first held section held by a first holding section of the pair of holding sections in the conveyance jig is formed, and a second coupling member that couples a second end portion of the first support member and a second end portion of the second support member and in which a second held section held by a second holding section of the pair of holding sections in the conveyance jig is formed, the assembly jig comprising:
a first positioning member configured to detachably hold the first coupling member such that the first held section is positioned at a first position at which the first held section is held by the first holding section;
a second positioning member configured to detachably hold the second coupling member such that the second held section is positioned at a second position at which the second held section is held by the second holding section;
a first moving section configured to support the first support member such that the first support member is parallel to a center line passing through the first position and the second position and configured to move the first support member in an orthogonal direction orthogonal to the center line; and
a second moving section configured to support the second support member such that the second support member is parallel to the center line on a side opposite to the first moving section with respect to the center line and configured to move the second support member in the orthogonal direction orthogonal to the center line.

4. The assembly jig for a board support member attachment according to claim 3, further comprising:
a loading plate on which the first positioning member, the second positioning member, the first moving section, and the second moving section are placed;
a first fixing section configured to fix the first moving section at any position within a movable range on the loading plate; and
a second fixing section configured to fix the second moving section at any position within a movable range on the loading plate.

5. A board support member attachment attached to a board support member configured to support a board when the board support member is held by a pair of holding sections, which face each other, of a conveyance jig and conveyed to a board work machine, the board support member attachment comprising:
a first support member attached to a first side of the board support member;
a second support member attached to a second side of the board support member facing the first side;
a third support member attached between the first support member and the second support member and extending along an extending direction of the first support member and the second support member; and
a pair of held sections provided at both end portions of the third support member in the extending direction and held by the pair of holding sections of the conveyance jig.
